(19) United States
(12) Patent Application Publication
(10) Pub. No.: US 2026/0081100 A1
(43) Pub. Date: Mar. 19, 2026

(54) FUNCTIONALIZED SLEEVE FOR SAMPLE HOLDER

(71) Applicant: FEI Company, Hillsboro, OR (US)

(72) Inventors: Bert Freitag, Weilerswist (DE); Johannes van den Oetelaar, Heeze (NL); Edwin Verschueren, Mierlo (NL)

(21) Appl. No.: 19/306,959

(22) Filed: Aug. 21, 2025

Related U.S. Application Data
(60) Provisional application No. 63/694,327, filed on Sep. 13, 2024.

(51) Int. Cl. H01J 37/20

(52) U.S. Cl. CPC H01J 37/20

(57) ABSTRACT

Methods and systems are provided for a system for supporting a sample. In one embodiment, a system includes a charged particle sample holder configured to hold a sample for analysis and a functionalized sleeve configured to receive the charged particle sample holder into an opening extending along an axis of the functionalized sleeve. When inserted, the functionalized sleeve encases at least a portion of the charged particle sample holder. The functionalized sleeve includes one or more extensions arranged along a top or bottom of the sample, the one or more extensions comprising stimulus and/or detection components

### FIELD OF THE INVENTION

The present disclosure relates generally to methods and systems for coupling a transmission electron microscope (TEM) sample holder to a scientific instrument. In particular, the present disclosure pertains to a sleeve for a sample holder that provides functionality for operations to be performed at the sample holder.

### BACKGROUND

Transmission electron microscope (TEM) sample holders may have a specific size (e.g., diameter) that is dependent on a manufacturer thereof. This may constrain use of a given sample holder to a specific scientific instrument (e.g., TEM system), which may demand access to multiple sample holders to allow a sample to be analyzed by different TEM systems. Furthermore, while a sample holder may be movable when coupled to a scientific instrument to allow a corresponding sample to be repositioned within the scientific instrument, the sample holder be capable of facilitating any additional actions or operations. It is, therefore, desirable to adapt a TEM sample holder to be usable with different TEM platforms and to provide functional capabilities at the sample holder to enhance analysis and/or processing of the sample.

### BRIEF SUMMARY

In at least one embodiment, a system includes a charged particle sample holder configured to hold a sample for analysis and a functionalized sleeve configured to receive the charged particle sample holder into an opening extending along an axis of the functionalized sleeve. When inserted, the functionalized sleeve encases at least a portion of the charged particle sample holder. Furthermore, the functionalized sleeve comprises one or more extensions arranged along a top or bottom of the sample, the one or more extensions comprising stimulus and/or detection components.

In another embodiment, a functionalized sleeve for a transmission electron microscope (TEM) sample holder includes a cylindrical shell, one or more extensions extending from a first end of the cylindrical shell, and sensing and/or detection components coupled to the one or more extensions. In addition, the functionalized sleeve includes one or more ports in the cylindrical shell, the one or more ports configured to pass feedthroughs of the sensing and/or detection components therethrough.

In yet another embodiment, a method using a sample support apparatus comprising a functionalized sleeve includes loading a sample onto a sample holder of the sample support apparatus, positioning the sample in a path of a charged particle beam, and activating stimulus components and/or detection components supported by the functionalized sleeve. The method further includes acquiring data from the sample as the sample is irradiated by the charged particle beam.

### BRIEF DESCRIPTION OF THE DRAWINGS

To easily identify the discussion of any particular element or act, the most significant digit or digits in a reference number refer to the figure number in which that element is first introduced.

FIG. 1 illustrates a cross-sectional diagram of a functionalized sleeve for a TEM sample holder, in accordance with one embodiment.

FIG. 2 illustrates a cross-sectional diagram of a sample support apparatus that includes the functionalized sleeve of FIG. 1 coupled to a sample holder, in accordance with one embodiment.

FIG. 3 illustrates a portion of a sample support apparatus that includes a first example of a functionalized sleeve, in accordance with one embodiment.

FIG. 4 illustrates a portion of a sample support apparatus that includes a second example of a functionalized sleeve, in accordance with one embodiment.

FIG. 5 illustrates a portion of a sample support apparatus that includes a third example of a functionalized sleeve, in accordance with one embodiment.

FIG. 6 illustrates a portion of the functionalized sleeve of FIG. 3, in accordance with one embodiment.

FIG. 7 illustrates the functionalized sleeve of FIG. 3 coupled to an engagement mechanism for aligning the functionalized sleeve with a scientific instrument, in accordance with one embodiment.

FIG. 8 illustrates the sample support apparatus of FIG. 3 coupled to a control mechanism of a scientific instrument, in accordance with one embodiment.

FIG. 9 illustrates a portion of a sample support apparatus with a functionalized sleeve that includes a vacuum transfer fitting in an open position, in accordance with one embodiment.

FIG. 10 illustrates the vacuum transfer fitting of FIG. 9 in a closed position, in accordance with one embodiment.

FIG. 11 illustrates a scientific instrument that can use a sample support apparatus having a functionalized sleeve, in accordance with one embodiment.

FIG. 12 illustrates a method for using a sample support apparatus having a functionalized sleeve, in accordance with one embodiment.

### DETAILED DESCRIPTION

The following description relates to systems and methods for increasing an adaptability and functionality of a TEM sample holder. This allows for more diverse capabilities of the sample holder, while maintaining an integrity of an associated sample supported by the sample holder.

Samples are supported within a TEM system by a TEM sample holder (hereafter, sample holder). The sample holder may maintain a sample within a TEM column such that the sample is irradiated with a charged particle beam (e.g., electron beam), allowing physical and chemical information to be acquired from the sample. In some instances, the sample holder may have limited capabilities, such as an allowable amount of movement to adjust a positioning of a sample within the TEM column. Such movement may include tilting the sample with respect to the electron beam, for example, and translating the sample in and out of the TEM column. Movement of the sample in and out of a TEM column via a sample holder, however, may at least briefly expose the sample to air.

Furthermore, sample holders may not have a structure or configuration that allows additional sample-related tasks or operations to be performed while a sample is supported (e.g., engaged) by a sample holder. For example, the sample holder may lack any openings to allow feedthroughs (e.g., couplings, connections, conduits for electrical, mechanical, and/or material delivery, etc.) to facilitate processes and operations to be performed at the sample. To allow such processing of the sample, removal of the sample from the TEM column may be demanded, which prolongs a workflow duration and may expose the sample to air and/or contaminants.

In addition, a sample holder may be manufactured with a geometry and dimensions that are specific to a particular TEM platform. For example, a sample holder produced by a specific manufacturer may only fit a TEM column produced by that manufacturer. As such, a user may be required to obtain a sample holder for each TEM platform that is to be used to analyze a sample, which may be costly and impractical.

In at least one embodiment, as described herein, a sample holder may be coupled to a functionalized sleeve that circumferentially surrounds at least a portion of the sample holder. For example, the sample holder may be inserted into the functionalized sleeve to form a sample support apparatus. The sample support apparatus may be inserted into TEM holder such that the sample holder maintains the sample securely in position within the TEM holder even if the sample holder has a geometry and/or dimensions that are not compatible with a receiving port of the TEM column. For example, the functionalized sleeve may be most effectively used when a sample holder has a diameter that is too small to be maintained stable within a receiving port of a TEM column. By coupling the sample holder to the functionalized sleeve, the diameter of the resulting sample support apparatus may be suitable for use with the TEM column. Moreover, the functionalized sleeve may include feedthroughs that allow control and/or electrical signals, as well as materials, to be delivered to or retrieved from components coupled to the functionalized sleeve.

As examples, the functionalized sleeve may be configured to provide functionality including stimulus functions (e.g., gas, light, electric, and/or magnetic stimuli), sensing functions (e.g., mirrors apertures, phase plates, detectors, etc.), and environmental functions (e.g., gas injection, vacuum, cryogenic conditions, etc.) within the sample support apparatus. The functionality may be implemented at a sample end of the sample support apparatus from a location above, below, or both above and below a sample plane of the apparatus. As a result, data collected from the sample may be enhanced while exposure of the sample to undesirable media (e.g., air and other contaminants) may be reduced.

By pairing a TEM sample holder with a functionalized sleeve, a user may experience greater freedom with respect to use of available sample holders for available TEM platforms. For example, constraints on coupling of a specific sample holder to an available TEM platform (e.g., having a common manufacturer) may be alleviated, thereby allowing sample holders of different geometries and/or dimensions to be compatible with a given TEM system. As such, a user may select a TEM column based on desired characteristics that are not bound by a compatibility of an available sample holder with the TEM column. In addition, in-situ and customized experiments, such as operations utilizing heating, cooling, detection, etc., may be performed via the functionalized sleeve, thus increasing an amount and diversity of data that can be acquired from the sample.

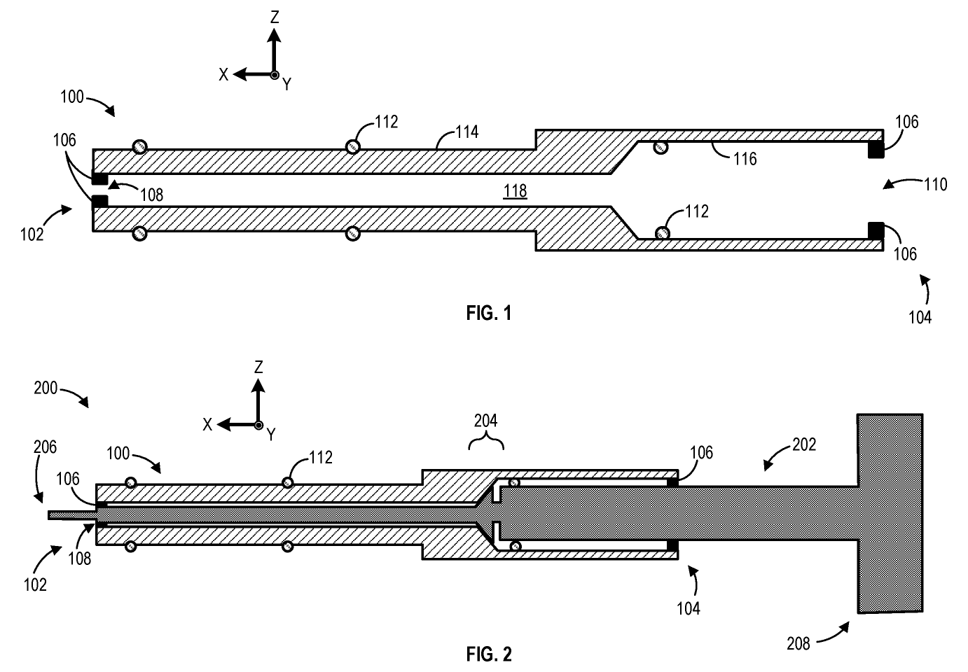

Further benefits provided by a functionalized sample holder sleeve as described as herein include economic advantages for use by allowing the user to select among different TEM column vendors without losing sample holder capabilities, an ability to maintain a sample within an innert environment even during sample transfer, and facilitate design of new experiments utilizing multimodal capabilities provided by the sleeve. The technical effect of utilizing a functionalized sample holder sleeve includes allowing for more robust experimental opportunities for the furtherance of science and engineering. The functionalized sleeve provides capabilities for multiple sample manipulation and data collection modalities while allowing for backward compatibility to older sample holders. Exemplary configurations of a functionalized sample holder sleeve are depicted in FIGS. 1-10 and described further below.

A cross-sectional diagram of an example functionalized sample holder sleeve 100 (hereafter, sleeve 100 for brevity) is illustrated in FIG. 1. The sleeve 100 has a sample end 102 and an external end 104. In at least one embodiment, the sample end 102 is positioned inside of a TEM column when the sleeve 100 is inserted into the TEM column and aligned with an electron beam of the TEM column, while the external end 104 may extend outside of the column. Each of the sample end 102 and the external end 104 incorporate feedthrough ports 106, which may include feedthroughs such as interfaces, openings, fittings, etc., to accommodate passage of conduits, wires, sensors, and other functional feedthroughs, therethrough. Furthermore, the feedthrough ports 106 may allow the feedthroughs to connect the sample end 102 of the sleeve 100 to devices, components, and/or apparatuses external to the sleeve 100 and/or external to the TEM column. In some examples, the feedthroughs may be used to provide connectivity (e.g., electronic and/or mechanical) to functionalized features or mechanisms at the sample end 102 of the sleeve 100.

The sample end 102 may include a first opening 108 and the external end 104 may include a second opening 110. The first opening 108 may allow a sample end of a sample holder to protrude therethrough and the second opening 110 may allow an external end of a sample holder to protrude therethrough (e.g., as shown in FIG. 2). The first opening 108 and the second opening 110 may define ends of an inner passage 118 that extends through a length of the sleeve 100 (e.g., along the x-direction). In at least one example, the z-direction may be parallel with a beam emission axis of a TEM electron beam.

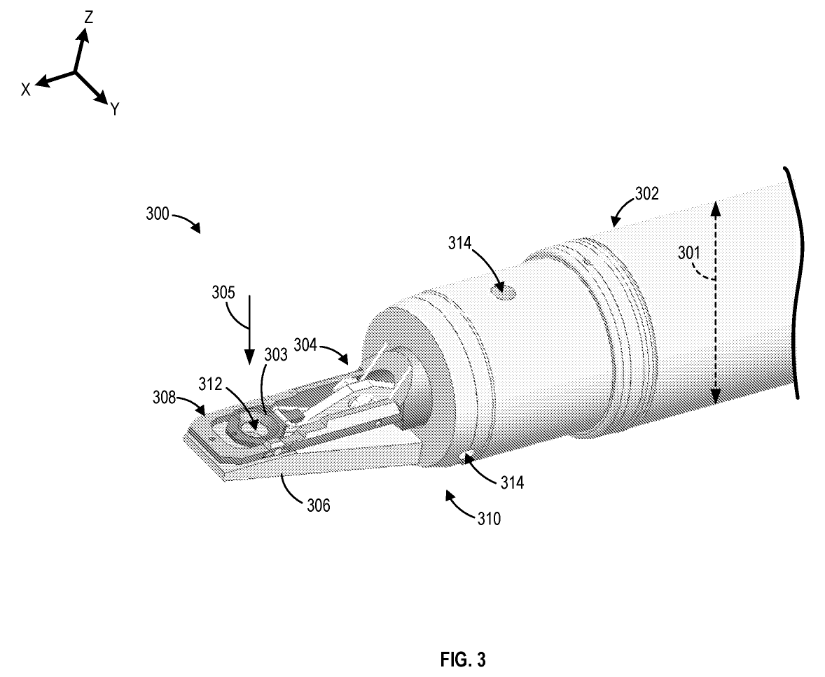

The sleeve 100 may also include alignment fixtures 112 located along both an outer surface 114 and an inner surface 116 of the sleeve 100. The alignment fixtures 112 along the outer surface 114 may align the sleeve 100 relative to the TEM column and the alignment fixtures 112 along the inner surface 116 may align the sleeve 100 relative to a TEM sample holder. For example, the alignment fixtures 112 may slide into grooves or indents in surfaces of the TEM column and the TEM sample holder to cause maintain the sleeve 100 aligned relative to the TEM column and/or the TEM sample holder aligned relative to the sleeve 100 once the alignment fixtures 112 are engaged with the corresponding grooves or indents. It will be appreciated that the embodiments of a functionalized sleeve illustrated in FIGS. 3-10, and described further below, may include alignments fixtures similar to the alignment fixtures 112 of FIG. 1 but are not shown for brevity.

A sample support apparatus 200 is illustrated in FIG. 2 that includes a sample holder 202 coupled to the sleeve 100 such that the sample holder 202 and the sleeve 100 are co-axial (e.g., an axis of the sample holder 202 along a length thereof is aligned with an axis of the sleeve 100 along a length thereof, where the lengths are defined along the x-direction). In at least one embodiment, the sleeve 100 may be configured to receive the sample holder 202. For example, the sample holder 202 may be inserted through the second opening 110 of the sleeve 100 and inserted until the sample holder 202 contacts portions of the inner surface 116 of the sleeve 100 at the sample end 102. As an example, a portion 204 of the sample holder 202 where a diameter (as defined along the z-direction) of the sample holder 202 widens may abut the inner surface 116 of the sleeve 100. This may inhibit further translation of the sample holder 202, relative to the sleeve 100, towards the sample end 102 of the sleeve 100.

A sample end 206 of the sample holder 202 may protrude or extend outwards from the first opening 108. At the sample end 206, a sample (e.g., a TEM sample) may be placed in the sample holder 202, which may maintain a stationary position of the sample relative to the sample holder 202 and to the TEM column. When the sample support apparatus 200 is inserted into the TEM column, the sample may be positioned in a path of an electron beam emitted by an electron source of the TEM column. In at least one embodiment, the sample end 206 of the sample holder 202 may be maintained under low pressure (e.g., vacuum) during, for example, preparation of the sample, transfer of the sample to the TEM column, and/or while the sample is inserted into the TEM column.

At an external end 208 of the sample holder 202, the sample holder 202 may protrude or extend outwards from the external end 104 of the sleeve 100. In at least one embodiment, both the external end 104 of the sleeve 100 and the external end 208 of the sample holder 202 may be external to the TEM column when the sample support apparatus 200 is inserted into the TEM column. This may allow the sample holder 202 to be adjusted and manipulated while the sample is being investigated using the TEM column.

As shown in FIG. 2, both an inner diameter and an outer diameter of the sleeve 100 (where the diameters are defined along the z-direction) are greater than the diameter of the sample holder 202 along the length or axis of the sample holder 202. At least a portion of the sample holder 202 may be circumferentially surrounded, or encased, by the sleeve 100. In instances where the sample holder 202 has a diameter that is too narrow for a receiving port of a TEM column, the sample holder 202 may be coupled to the sleeve 100 and inserted into the TEM column as the sample support apparatus 200, where the sample support apparatus 200 has an outer diameter that is compatible with the receiving port of the TEM column. In instances where the diameter of the sample holder 202 is compatible with a receiving port of a TEM column, the sleeve 100 may be obviated, and the sample holder 202 may be inserted into the TEM column without using the sleeve 100.

As described above, the feedthrough ports 106 of the sleeve 100 may impart the sleeve 100 with various functionalities to be applied to a sample supported by the sample holder 202. For example, the feedthrough ports 106 may support stimulus components including, but not limited to, a heating component, a cooling component, a gas supply directed toward the sample, an electric source, a magnetic source, and/or a light source. The feedthrough ports 106 may also support one or more detection components, including, but not limited to, a secondary electron detector, a backscatter electron detector, mirrors for light collection, specialized apertures, phase plates, an optical detector, and/or an x-ray detector, as well as any additional components for various stimulus or detection/sensing schemes that may be deployed while interrogating a sample with an electron beam. A variety of experimental conditions and types of experiments may be expanded as a result of utilizing a functionalized sleeve having feedthrough ports, as described herein.

In some examples, a functionalized sample sleeve of a sample support apparatus may include one or more structural elements to support integration of one or more functionalities into the sleeve to allow the functionalities to be applied to a sample. FIG. 3 depicts a first example of a sample support apparatus 300 that includes a functionalized sample holder sleeve 302 having such a structural element. The sample support apparatus 300 may be an embodiment of the sample support apparatus 200 of FIG. 2. A sample holder 304 is coupled to the sleeve 302. The sample holder 304 includes a sample ring 303 in which a sample (e.g., a TEM grid) may be placed for investigation using a TEM column. In at least one embodiment, the sleeve 302 is a cylindrical shell or tube having a length, relative to the x-direction, that is greater than a diameter 301 of the sleeve 302.

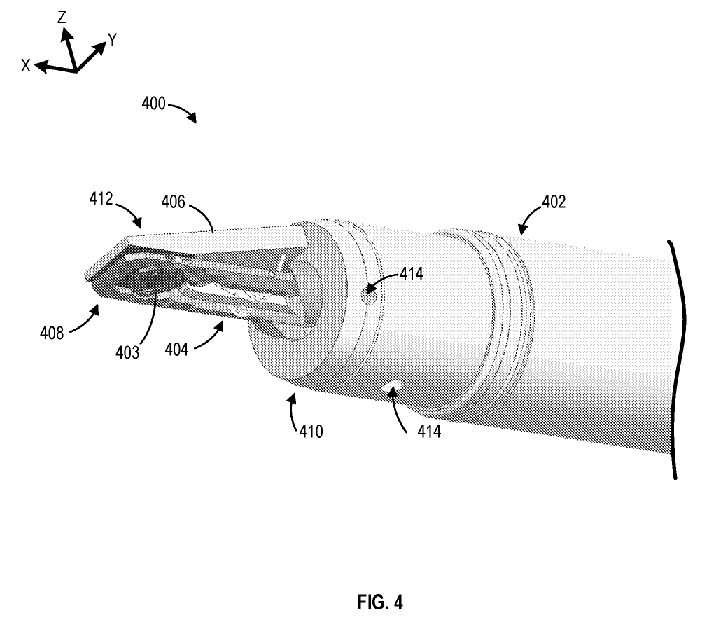

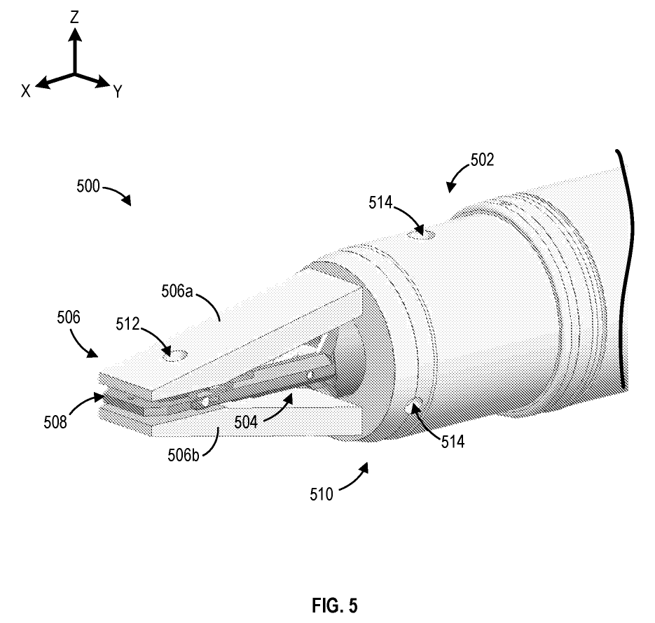

As shown in FIG. 3, the sleeve 302 includes an extension 306 positioned below (e.g., relative to the z-direction) a sample end 308 of the sample holder 304 that protrudes outside of the sleeve 302. For example, the sample end 308 of the sample holder 304 may extend along the x-direction from an opening (e.g., similar to the first opening 108 of FIG. 1) at a sample end 310 of the sleeve 302. The extension 306 may extend from the sample end 310 of the sleeve 302 in parallel with the sample end 308 of the sample holder 304. In one example, as shown in FIG. 3, a length of the extension 306 along the x-direction may match an amount that the sample end 308 of the sample holder 304 protrudes from the sleeve 302, also along the x-direction. In other examples, however, the length of the extension 306 may not be equal to the protrusion of the sample end 308 of the sample holder 304 from the sleeve 302. For example, the length of the extension 306 may be greater or less than the protrusion of the sample end 308 of the sample holder 304. Similar variability is applicable to extensions shown in FIGS. 4 and 5.

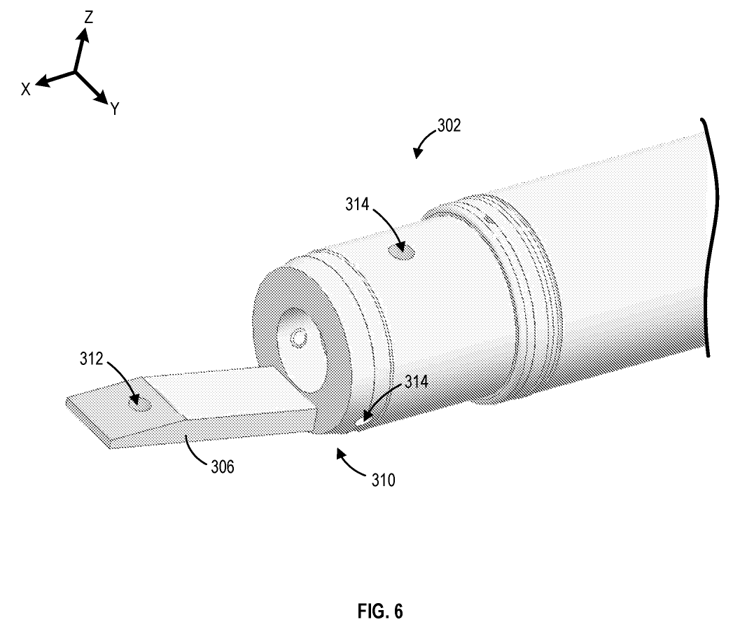

Moreover, the extension 306 is arranged to be below a sample, when the sample is located in the sample ring 303, with respect to a direction of a beam emitted by an electron source (as indicated by arrow 305). The extension 306 is thereby positioned along a bottom of the sample. The extension 306 may be a protrusion coupled to and extending outwards, along the x-axis, from the sample end 310 of the sleeve 302. In at least one embodiment, the extension 306 may include an aperture 312 that is aligned with a central opening of the sample ring 303, as shown more clearly in FIG. 6.

The sleeve 302 is depicted in FIG. 6 without the sample holder 304 coupled thereto. The aperture 312 may be a through-hole that extends entirely through a thickness (e.g., as defined along the z-axis) of the extension 306. The aperture 312 may be aligned with the central opening of the sample ring 303 such that an electron beam transmitted through the sample may pass through the aperture 312 unaffected and unimpeded by the extension 306. The extension 306 may support one or more functional components (not shown), including stimulus and detection components, where the functional components may be arranged on the extension 306, around the aperture 312. Alternatively, if arranged in a path of the electron beam, the functional components may also include an aperture for beam passage therethrough.

Returning to FIG. 3, the sleeve 302 may also include one or more feedthrough ports 314. The feedthrough ports 314 may allow passage of connections through the sleeve 302, between the functional components and devices located external to the sample support apparatus 300. It will be appreciated that a size, shape, and relative positioning of feedthrough ports, as well as other components of the sample support apparatus depicted in FIGS. 3-10 are non-limiting examples, and variations are possible without departing from the scope of the present disclosure.

In FIG. 4, a second example of a sample support apparatus 400 is shown that includes a functionalized sample holder sleeve 402 coupled to and surrounding at least a portion of a sample holder 404. The sample support sample support apparatus 400 may be an embodiment of the sample support apparatus 200 of FIG. 2 and may be similar to the sample support apparatus 300 of FIG. 3 except for a positioning of a structural element that supports integration of functionality into the sleeve 402. The sleeve 402 includes an extension 406 that is positioned above (e.g., relative to the z-direction) a sample end 408 of the sample holder 404 and extends from a sample end 410 of the sleeve 402. The extension 406 is thereby arranged along a top of a sample supported by the sample holder 404. The sample end 408 protrudes from an opening (e.g., similar to the first opening 108 of FIG. 1) at the sample end 410 of the sleeve 402. The sample end 408 of the sample holder 404 includes a sample ring 403 to support a sample. In at least one embodiment, the extension 406 includes an aperture 412 (obscured in FIG. 4), such as the aperture 312 of FIG. 3, that is aligned with a central opening of the sample ring 403. The aperture of the 406 may allow an electron beam to pass through and impinge on the sample. Various functional components (not shown), including stimulus and detection components, may be arranged along the extension 406 and directed at the sample. If positioned in a path of the electron beam, the functional components may include apertures to accommodate beam passage therethrough.

The sleeve 402 may further include one or more feedthrough ports 414. The feedthrough ports 414 may allow passage of connections through the sleeve 402, between the functional components and devices located external to the sample support apparatus 400.

A third example of a sample support apparatus 500 is shown that includes a functionalized sample holder sleeve 502 to which a sample holder 504 is coupled. The sample support apparatus 500 may be an embodiment of the sample support apparatus 200 of FIG. 2 and may combine structural elements of the sample support apparatuses 300 and 400 of FIGS. 3 and 4. For example, the sleeve 502 includes a set of extensions 506 protruding outwards, along the x-direction, from a sample end 510 of the sleeve 502. The set of extensions 506 includes an upper extension 506a that may be similar to the extension 406 of FIG. 4 and a lower extension 506b that may be similar to the extension 306 of FIG. 3. The upper extension 506a may extend above a sample end 508 of the sample holder 504 and the lower extension 506b may extend below the sample end 508 of the sample holder 504, where references to above and below are oriented with respect to the z-direction.

The sample end 508 of the sample holder 504 may be similar to the sample end 308 of the sample holder 304 of FIG. 3 or the sample end 408 of the sample holder 404 of FIG. 4. For example, although not visible in FIG. 5, the sample end 508 of the sample holder 504 may include a sample ring, such as the sample ring 303 of FIG. 3 or the sample ring 403 of FIG. 4. Each of the set of extensions 506 may include an aperture 512 that is aligned with a central opening of the sample ring. By arranging extensions above and below the sample end 508 of the sample holder 504, functional components, including stimulus and detection components, may be incorporated into the sample support apparatus 500, in close proximity to a sample, without interfering with beam transmission. Feedthroughs of the functional components may be passed through feedthrough ports 514 of the sleeve 502 to provide functionality to the functional components.

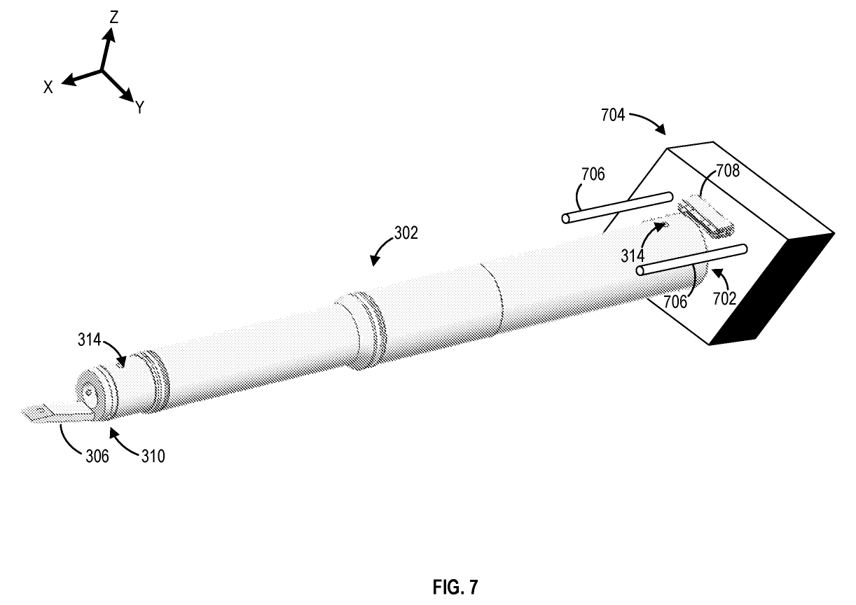

In FIG. 7, an external end 702 of the sleeve 302 of FIG. 3 is shown having an engagement mechanism 704. The engagement mechanism 704 may be arranged at an opposite end of the sleeve 302 from the sample end 310 of the sleeve 302. The external end 702 may protrude outside of a TEM column when the sleeve 302 is inserted into a receiving port of the TEM column. The engagement mechanism 704 may be used to align and secure the sleeve 302 to the TEM column. For example, the engagement mechanism 704 may engage mechanisms or structures at the TEM column to maintain a position of the sample support apparatus (e.g., the sample support apparatus 300 of FIG. 3) at a desired alignment relative to an electron beam and to internal components of the TEM column. The engagement mechanism 704 may include one or more alignment posts 706 that may slide into corresponding alignment holes of the TEM column. The engagement mechanism 704 may further include one or more connectors 708 that may provide electronic and fluidic connections between the sample end 310 of the sleeve 302 and devices external to the sleeve 302.

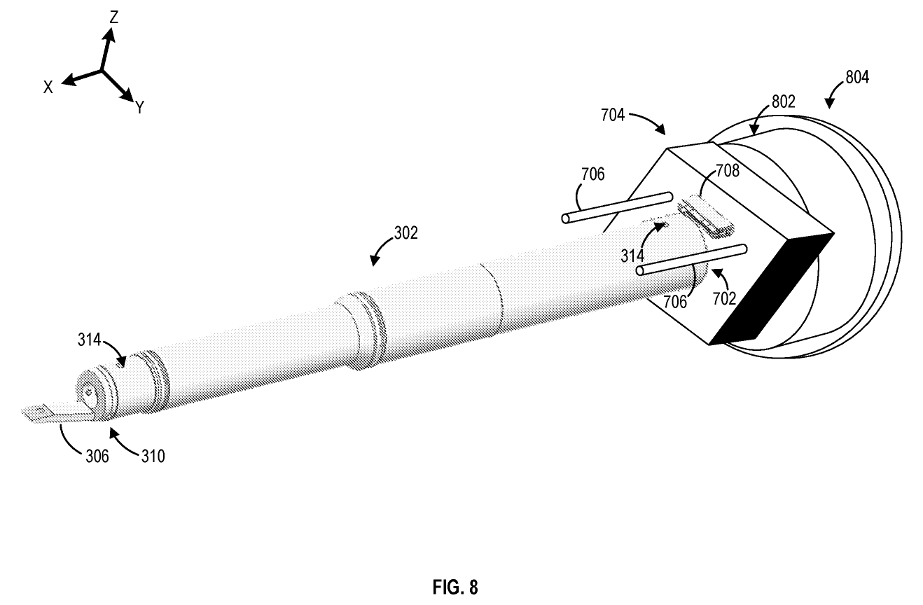

The sample support apparatus 300 of FIG. 3, including the sleeve 302, the sample holder 304, and the engagement mechanism 704 of FIG. 7, is illustrated in FIG. 8 coupled to control mechanisms 802. The control mechanisms 802 may be used to control components of a TEM system having a TEM column in which the sample support apparatus 300 is to be inserted. For example, the control mechanisms 802 may allow the sample holder 304 to be tilted, rotated, or otherwise re-positioned in 3-dimensional space relative to an electron beam.

The control mechanisms 802 may be coupled to the sample support apparatus 300 at a location adjacent to the engagement mechanism 704 along an external end 804 of the sample holder 304. In at least one embodiment, the control mechanisms 802 may abut the engagement mechanism 704 along the x-direction and may be engaged with the engagement mechanism 704. As described previously, the external end 804 of the sample holder 304 may protrude outside of the TEM column when the sample support apparatus 300 is inserted into the TEM column. In some examples, at least a portion of the control mechanisms 802 may also protrude outside of the TEM column. In other examples, however, the entire sample support apparatus 300 may instead be placed inside of a load lock, such as during loading of the sample into the sample holder 304 and storage of the sample when the sample is not undergoing investigation using the TEM column. Furthermore, in at least some instances, the TEM column may include a sample holder engagement component that fully encloses the sample support apparatus 300 when the sample support apparatus 300 is inserted into the TEM column.

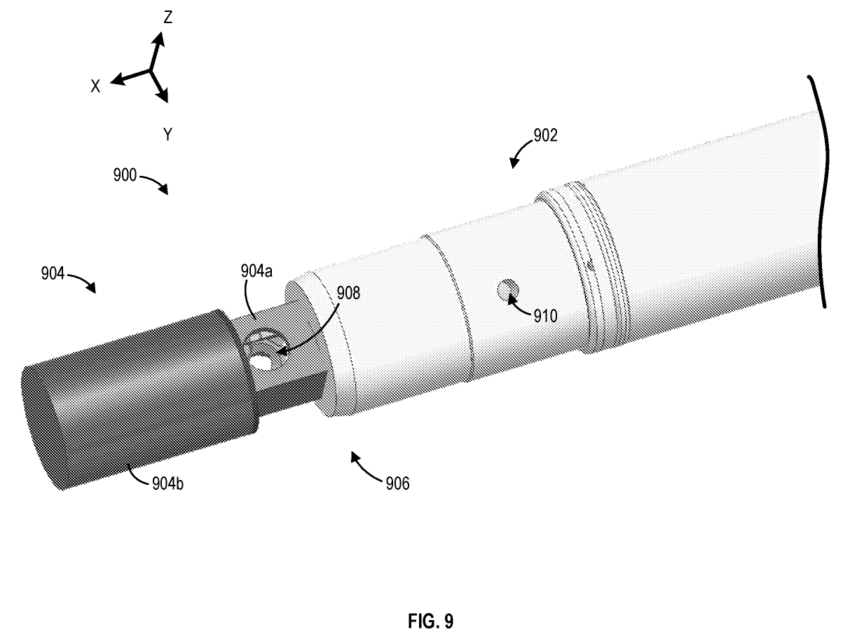

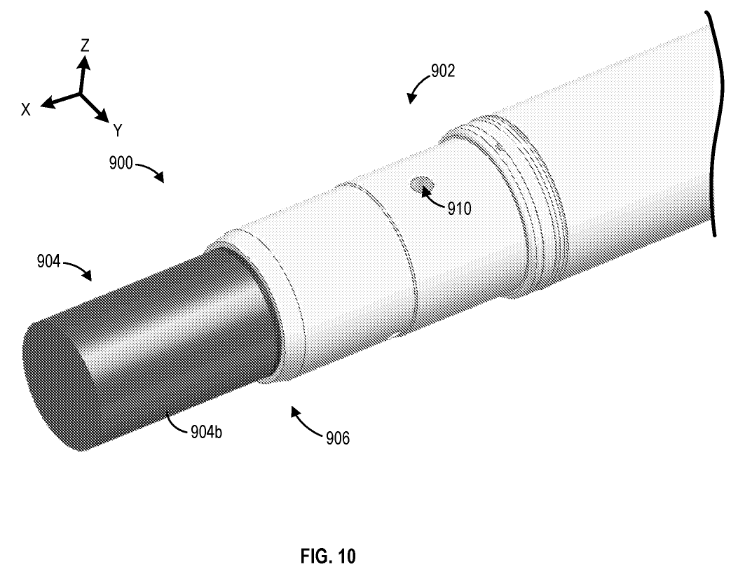

In at least one embodiment, a functionalized TEM sample holder sleeve may be used in conjunction with a sample holder supporting a sample to be maintained under low pressure (e.g., vacuum). As such, the sleeve may include a structural element used to seal a portion of the sample holder such that low pressure conditions are maintained. As an example, as shown in FIGS. 9 and 10, a sample support apparatus 900 may include a functionalized sleeve 902 that has a vacuum transfer fitting 904. The vacuum transfer fitting 904 may seal the sample therein to isolate the sample from an ambient environment surrounding the sample support apparatus 900.

A sample holder similar to the sample holders depicted in FIGS. 3-5 and 8 may be coupled to and protrude (e.g., along the x-direction) from a sample end 906 of the sleeve 902. In at least one embodiment, the sleeve 902 may further include one or more extensions, such as the extensions illustrated in FIGS. 3-8, in addition to the vacuum transfer fitting 904. In other examples, however, the sleeve 902 may include the vacuum transfer fitting 904 without any additional extensions. In such examples, at least a portion of the vacuum transfer fitting 904 may be an extension of the sleeve 902 that has a different geometry than the extensions depicted in FIGS. 3-8.

The vacuum transfer fitting 904 is illustrated in an open position in FIG. 9 and in a closed position in FIG. 10. As shown in FIG. 9, the vacuum transfer fitting 904 includes an inner portion 904a and an outer portion 904b. The inner portion 904a may be an extension that is coupled to and extends from the sample end 906 of the sleeve 902 and may be configured to surround the sample end of the sample holder. The inner portion 904a may have a box-like geometry (e.g., shaped as a rectangular prism or cuboid) and may include apertures 908 arranged in faces of the inner portion 904a intersecting the z-direction. The apertures 908 may be aligned with a central opening of a sample ring of the sample holder to allow an electron beam to be transmitted through the inner portion 904a. One or more functional structures (e.g., stimulation and/or detection components) may be coupled to the inner portion 904a, such as along inner surfaces of the inner portion 904a proximate to a sample supported by the sample end of the sample holder.

The outer portion 904b of the vacuum transfer fitting 904 may be a cap that entirely encloses the inner portion 904a when coupled to and engaged with the sample end 906 of the sleeve 902. In other words, the outer portion 904b may be capable of covering the inner portion 904a and the sample end of the sample holder. For example, as shown in FIG. 10, the inner portion 904a of the vacuum transfer fitting 904 may be inserted into an inner cavity of the outer portion 904b. The vacuum transfer fitting 904 may be adjusted to the closed position depicted in FIG. 10 by pressing an edge of the outer portion 904b, at an open end of the outer portion 904b, such that the edge abuts and couples to the sample end 906 of the sleeve 902.

In at least one embodiment, the control signal may be provided through the sleeve 902, such as via one or more feedthrough ports 910, to one or more mechanisms to facilitate automated adjustment of the vacuum transfer fitting 904 between the open and closed positions shown in FIGS. 9A and 9B, respectively. For example, the vacuum transfer fitting 904 may be adjusted to the open position when the sample support apparatus 900 is inserted into a TEM column for sample interrogation using an electron beam. Prior to insertion into the TEM column, the sample may be prepared and loaded onto the sample holder in sample preparation apparatus, such as, for example, a load lock. Within the sample preparation apparatus, the sample and the sample support apparatus 900 may be maintained under low pressure as the sample is loaded into the sample support apparatus 900. As one example, the sample may be loaded under low pressure conditions similar to a low pressure environment of the TEM column. The vacuum transfer fitting 904 may be adjusted to the closed position once sample loading is complete and the sample may be transferred to the TEM column without exposing the TEM sample to ambient conditions. The vacuum transfer fitting 904 may only be adjusted to the open position in a suitably low pressure and/or clean environment, thereby maintaining sample integrity.

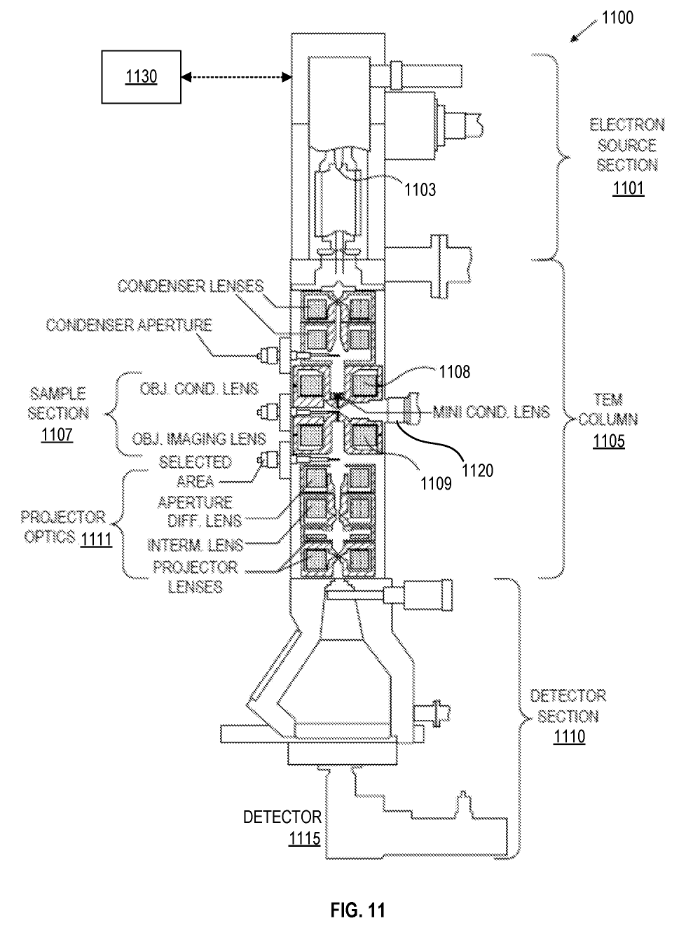

FIG. 11 depicts an example of an environment in which a functional sample holder sleeve, such as any of the sleeves illustrated in FIGS. 1-10, may be used in conjunction with a sample holder to allow a sample to be investigated using a charged particle beam. The environment of FIG. 3 is a TEM system 1100 that includes an electron source section 1101, including an electron source 1103, a TEM column 1105 including a sample section 1107, an objective probe-forming lens 1108, an objective imaging lens 1109, a projection optics system 1111, and a detector section 1110 including, for example, one or more detectors 1115.

In brief, the electron source section 1101 includes electronics configured to energize a source of charged particles, which can include a high-voltage field-emission source or other sources of emitted electrons, such that a beam of electrons is formed and conducted through a vacuum into the TEM column 1105. The TEM column 1105 includes components for beam forming, including electromagnetic lenses and/or electrostatic lenses, and multiple apertures to control properties of the beam of electrons. The TEM column 1105 includes sample section 1107 components such as condenser lenses, objective lenses (e.g., the objective probe-forming lens 1108 and the objective imaging lens 1109), a minicondenser lens, and a sample support apparatus 1120. The sample section 1107 hosts a sample through which the beam of electrons can be transmitted. The TEM column 1104 further includes projector optics system 1111 components such as projector lenses, differential and intermediate lenses, aberration correctors, deflectors, stigmators, among others, as well as corresponding apertures (e.g., a selected area diffraction aperture).

In at least one embodiment, as described above, the sample support apparatus 1120 of the sample section 1107 may be used to support the sample and maintain a position of the sample relative to the beam of electrons. At least a portion of a sample holder of the sample support apparatus 1120 may be circumferentially surrounded by a functionalized sleeve that imparts functionality to the functionalized sleeve such that various stimulus and detection components can be applied to the sample to acquire data. In some examples, the functionalized sleeve may include, in addition to or in place of one or more extensions that support the stimulus and detection components, a vacuum transfer fitting that can be used to enclose the sample during transfer of the sample support apparatus from another apparatus (e.g., a sample preparation or loading apparatus) to the TEM column 105. This may allow the sample to be shielded from contaminants, contact with external objects, and/or maintained under a desired low pressure environment.

The detector section 1110 includes one or more types of detector, sensor, screen, and/or optics configured to generate images, spectra, and other data for use in sample imaging and/or microanalysis. For example, the detectors can include a pixelated electron detector, a secondary electron detector, one or more cameras, an electron energy loss spectroscopy spectrometer, an energy dispersive x-ray spectroscopy detector, among others.

The TEM system 1100 may be electronically coupled to a control system 1130 either wirelessly or via a hard-wired connection. The control system 1130 may include one or more computing devices with one or more processors to control components of the TEM system 1100. For example, the control system 1130 may include one or more user interfaces to receive requests and other inputs from a user. The control system 1130 may perform various tasks and operations in response to the requests and input. As an example, upon detection that the sample support apparatus 1120 is inserted into the TEM column 11054 and, in response to receiving a request to investigate the sample, the control system 1130 may command activation of the electron source to emit an electron beam with a target energy density, beam current, spot size, etc. The control system 1130 may also command initiation and termination of data acquisition at the detectors 1115. In at least one embodiment, the control system 1130 may send instructions to the sample support apparatus 1120, when the sample support apparatus 1120 includes a vacuum transfer fitting, to adjust the vacuum transfer fitting between open and closed positions. The control system 1130 may further include memory (e.g., non-transitory memory) to store executable instructions, as well as other information, such as collected data.

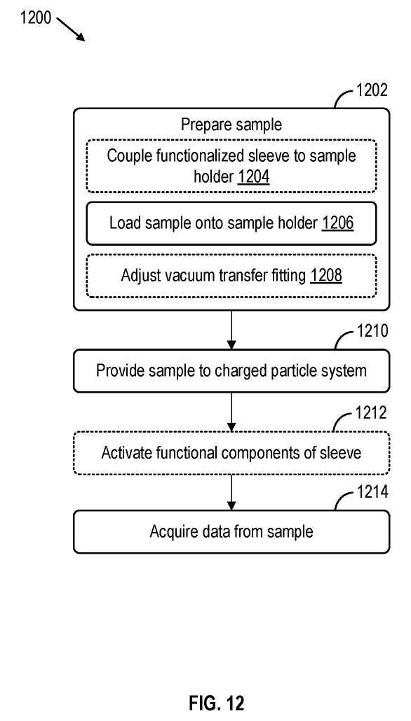

FIG. 12 shows an example of a method 1200 for using a sample support apparatus in a charged particle system, where the sample support apparatus includes a functionalized sleeve. In at least one embodiment, the charged particle system may be the TEM system 1100 of FIG. 11. The sample support apparatus may be similar to any of the sample support apparatuses illustrated in FIGS. 2-5, or 8-10. At least a portion of the method 1200 may be performed by a user or operator (e.g., manually), by an automated process controlled via a control system, such as the control system 1130 of FIG. 11, or a combination thereof. Operations are illustrated once each and in a particular order in FIG. 12, but the operations may be reordered and/or repeated as desired and appropriate (e.g., different operations performed may be performed in parallel, as suitable).

It will be appreciated that in some instances, use of the functionalized sleeve may be obviated, such as when a TEM sample holder has a diameter that is similar to an inner diameter of a receiving port of the TEM system. For example, a difference between the inner diameter of the receiving port and the diameter of the TEM sample holder may too small to accommodate an increase in diameter cause by coupling of the sleeve to the sample holder. In such examples, the sample holder may be used without the sleeve, although the sample holder may be unable to support functionalities that are provided by the sleeve.

At 1202, the method includes preparing the sample for investigation and analysis using a charged particle beam. In at least one embodiment, preparing the sample for investigation allows the sample to be interrogated by irradiating the sample with the charged particle beam (e.g., electron beam) to collect data based on interaction between the sample and the charged particle beam. For example, the data may include images, elemental composition, crystallographic information, morphology, electronic structure, chemical bonding information, among others. Preparing the sample may include operations as shown in 1204-1208.

In one instance, preparing the sample may optionally include coupling the functionalized sleeve to a sample holder at 1204. For example, the sleeve and the sample holder may be placed in a sample preparation apparatus and the sample holder may be inserted into the into the sleeve such that the sleeve circumferentially surrounds at least a portion of the sample holder along a length of the sample holder, with a sample end of the sample holder protruding from a sample end of the sleeve. In at least one embodiment, the coupling causes one or more structural elements of the sleeve to be positioned proximate to the sample end of the sample holder, where the one or more structural elements may be extensions (e.g., as shown in FIGS. 3-8) that support one or more functional components, including stimulus and detection components. In another embodiment, one or more structural elements may include a vacuum transfer fitting (e.g., as shown in FIGS. 9 and 10) and the coupling causes the sample end of the sample holder to be enclosed by an inner portion of the vacuum transfer fitting. The inner portion of the vacuum transfer fitting may similarly support functional components. Moreover, the sleeve may include one or more of the extension(s) or the vacuum transfer fitting, where one or more of the extension(s) or the vacuum transfer fitting may support the functional components.

Preparing the sample for investigation may include loading the sample onto the sample holder of the sample support apparatus at 1206. As an example, the sample support apparatus and the sample may be stored or placed in a sample preparation apparatus. The sample may be placed onto a sample end of the sample holder, such as onto a sample ring of the sample holder, within the sample preparation apparatus. In other examples, the sample may be prepared outside of a sample preparation apparatus, e.g., under ambient conditions.

Although the coupling of the sleeve to the sample holder is shown as being performed before loading the sample onto the sample holder in FIG. 12, it will be appreciated that in some instances, the functionalized sleeve may instead be coupled to the sample holder after the sample is loaded. For example, when the sleeve is configured as shown in FIGS. 3 and 6-8, where the sleeve includes one extension that is positioned below the sample ring of the sample holder, the sample may be loaded onto the sample holder before or after the sleeve is coupled to the sample holder. In sleeve configurations that include an extension arranged above the sample ring (e.g., as shown in FIGS. 4 and 5), the sample may be loaded onto the sample ring before the sleeve is coupled to the sample holder. Additionally, when the sleeve includes a vacuum transfer fitting (e.g., as shown in FIGS. 9 and 10), the sample may also be loaded onto the sample ring before the sleeve is coupled to the sample holder.

Preparing the sample may further optionally include adjusting the vacuum transfer fitting at 1208. For example, when the sleeve includes the vacuum transfer fitting, the fitting may be initially in an open position (e.g., as shown in FIG. 9) while the sample is loaded onto the sample holder and the sleeve is coupled to the sample holder within the sample preparation apparatus. During these operations, the sample preparation apparatus may maintain a low pressure environment therein. By adjusting the vacuum transfer fitting to a closed position (e.g., as shown in FIG. 10) the low pressure environment of the sample preparation apparatus is maintained within the vacuum transfer fitting where the sample is located.

At 1210, the method 1200 includes providing the sample to the charged particle system (e.g., to a TEM column of the TEM system). For example, the sample support apparatus may be inserted into a receiving port of the TEM column. In at least one embodiment, the sample support apparatus may include an engagement mechanism, such as the engagement mechanism 704 of FIG. 7, to align the sample support apparatus with the TEM column. By inserting the sample support apparatus into the TEM column according to the engagement mechanism, the sample may be aligned with the charged particle beam emitted by an electron source of the TEM column. In at least one embodiment, when the sample support apparatus includes the vacuum transfer fitting, the fitting may be adjusted to the open position once the sample is provided to the charged particle system. In other examples, however, the vacuum transfer fitting may be adjusted to the open position during subsequent operations of the method 1200 (e.g., during 1212 or 1214).

At 1212, the method 1200 includes activating functional components of the sleeve. For instance, one or more stimulus components and/or one or more detection components coupled to the sleeve may be activated and/or energized via feedthroughs that may be passed through feedthrough ports of the sleeve. The one or more stimulus components may be used to apply stimuli to the sample to, for example, facilitate reactions at the sample that can be monitored using the TEM system. A progress or status of stimulation provided by the one or more stimulus components may be detected and/or monitored using the one or more detection components (e.g., as feedback).

At 1214, the method 1200 includes acquiring data from the sample. For example, detectors of the TEM system may be instructed (e.g., by the control system) to collect information from the sample as the sample is irradiated by the electron beam and, optionally, exposed to functionalities provided by the functionalized sleeve.

In an embodiment, a system comprises a charged particle sample holder configured to hold a sample for analysis and a functionalized sleeve configured to receive the charged particle sample holder into an opening extending along an axis of the functionalized sleeve so that, when inserted, the functionalized sleeve encases at least a portion of the charged particle sample holder, wherein the functionalized sleeve comprises one or more extensions arranged along a top or bottom of the sample, the one or more extensions comprising stimulus and/or detection components. In a first example, the functionalized sleeve also includes a vacuum transfer fitting capable of covering a sample end of the charged particle sample holder. In another example that includes one or more of the previous examples, the vacuum transfer fitting is adjustable between an open position and a closed position, and in the open position, the sample is exposed to an environment surrounding the charged particle sample holder and in the closed position, the sample is sealed within the vacuum transfer fitting. In another example that includes one or more of the previous examples, the stimulus components comprise one or more of a heating component, a cooling component, a gas supply directed toward the sample, an electric source, a magnetic source, or a light source component. In another example that includes one or more of the previous examples, the detection components comprise one or more of a secondary electron detector, a backscatter electron detector, mirrors for light collection, specialized apertures, phase plates, an optical detector and/or an x-ray detector. In another example that includes one or more of the previous examples, the functionalized sleeve comprises one or more ports to pass feedthroughs of the stimulus and/or detection components therethrough. In another example that includes one or more of the previous examples, the axis is aligned with a length of the functionalized sleeve, and the one or more extensions protrude from a sample end of the functionalized sleeve along the axis of the functionalized sleeve. In another example that includes one or more of the previous examples, the functionalized sleeve comprises, at an end opposite of a sample end of the functionalized sleeve, an engagement mechanism to engage the functionalized sleeve with a charged particle column.

In an embodiment, a functionalized sleeve for a transmission electron microscope (TEM) sample holder comprises a cylindrical shell, one or more extensions extending from a first end of the cylindrical shell, sensing and/or detection components coupled to the one or more extensions, and one or more ports in the cylindrical shell, the one or more ports configured to pass feedthroughs of the sensing and/or detection components therethrough. In a first example, an inner passage of the cylindrical shell is configured to receive the TEM sample holder and the cylindrical shell circumferentially surrounds at least a portion of a length of the sample holder when the sample holder is inserted into the cylindrical shell. In another example that includes one or more of the previous examples, the one or more extensions extend in a direction along a length of the functionalized sleeve above and/or below a sample end of the TEM sample holder. In another example that includes one or more of the previous examples, the one or more extensions comprise one or more apertures aligned with a sample ring of the TEM sample holder, and the apertures are aligned with an emission path of an electron beam when the TEM sample holder is inserted, while coupled to the functionalized sleeve, into a TEM column. In another example that includes one or more of the previous examples, the cylindrical shell includes one or more alignment fixtures along an outer surface and/or an inner surface of the cylindrical shell. In another example that includes one or more of the previous examples, the functionalized sleeve further comprises an engagement mechanism at a second end of the cylindrical shell, the second end opposite of the first end, and the engagement mechanism comprises one or more alignment posts to align the functionalized sleeve with a receiving port of a TEM column. In another example that includes one or more of the previous examples, the one or more extensions comprise an inner portion of a vacuum transfer fitting that surrounds a sample end of the TEM sample holder, and the functionalized sleeve further comprises an outer portion of the vacuum transfer fitting that is configured to couple to the first end of the functionalized sleeve to isolate the sample end of the TEM sample holder from an ambient environment surrounding the functionalized sleeve.

In an embodiment, a method for using a sample support apparatus comprising a functionalized sleeve comprises loading a sample onto a sample holder of the sample support apparatus, positioning the sample in a path of a charged particle beam, activating stimulus components and/or detection components supported by the functionalized sleeve, and acquiring data from the sample as the sample is irradiated by the charged particle beam. In a first example, the method further comprises coupling an outer portion of a vacuum transfer fitting to a sample end of the functionalized sleeve to maintain the sample in a low pressure environment within the vacuum transfer fitting. In another example that includes one or more of the previous examples, when the sample support apparatus is coupled to a charged particle column, the method further comprises adjusting the vacuum transfer fitting from a closed position to an open position to position the sample in the path of the charged particle beam. In another example that includes one or more of the previous examples, loading the sample comprises positioning the sample proximate to one or more extensions of the functionalized sleeve, and the sample is aligned with an aperture of each of the one or more extensions when the sample is loaded. In another example that includes one or more of the previous examples, the sample holder is inserted into the functionalized sleeve such that a sample end of the sample holder protrudes out of a sample end of the functionalized sleeve, and the sample holder is co-axial with the functionalized sleeve along lengths thereof when the sample holder is inserted into the functionalized sleeve.

While the present disclosure has been described in detail with reference to specific embodiments, it will be apparent to those skilled in the art that various modifications and changes can be made without departing from the spirit and scope of the disclosure. Accordingly, the specification and drawings are to be regarded in an illustrative rather than a restrictive sense.

What is claimed is:

1. A system comprising:
a charged particle sample holder configured to hold a sample for analysis; and
a functionalized sleeve configured to receive the charged particle sample holder into an opening extending along an axis of the functionalized sleeve so that, when inserted, the functionalized sleeve encases at least a portion of the charged particle sample holder;
wherein the functionalized sleeve comprises one or more extensions arranged along a top or bottom of the sample, the one or more extensions comprising stimulus and/or detection components.

2. The system of claim 1, wherein the functionalized sleeve also includes a vacuum transfer fitting capable of covering a sample end of the charged particle sample holder.

3. The system of claim 2, wherein the vacuum transfer fitting is adjustable between an open position and a closed position, and wherein in the open position, the sample is exposed to an environment surrounding the charged particle sample holder and in the closed position, the sample is sealed within the vacuum transfer fitting.

4. The system of claim 1, wherein the stimulus components comprise one or more of a heating component, a cooling component, a gas supply directed toward the sample, an electric source, a magnetic source, or a light source component.

5. The system of claim 1, wherein the detection components comprise one or more of a secondary electron detector, a backscatter electron detector, mirrors for light collection, specialized apertures, phase plates, an optical detector and/or an x-ray detector.

6. The system of claim 1, wherein the functionalized sleeve comprises one or more ports to pass feedthroughs of the stimulus and/or detection components therethrough.

7. The system of claim 1, wherein the axis is aligned with a length of the functionalized sleeve, and wherein the one or more extensions protrude from a sample end of the functionalized sleeve along the axis of the functionalized sleeve.

8. The system of claim 1, wherein the functionalized sleeve comprises, at an end opposite of a sample end of the functionalized sleeve, an engagement mechanism to engage the functionalized sleeve with a charged particle column.

9. A functionalized sleeve for a transmission electron microscope (TEM) sample holder, comprising:
a cylindrical shell;
one or more extensions extending from a first end of the cylindrical shell;
sensing and/or detection components coupled to the one or more extensions; and
one or more ports in the cylindrical shell, the one or more ports configured to pass feedthroughs of the sensing and/or detection components therethrough.

10. The functionalized sleeve of claim 9, wherein an inner passage of the cylindrical shell is configured to receive the TEM sample holder and wherein the cylindrical shell circumferentially surrounds at least a portion of a length of the sample holder when the sample holder is inserted into the cylindrical shell.

11. The functionalized sleeve of claim 9, wherein the one or more extensions extend in a direction along a length of the functionalized sleeve above and/or below a sample end of the TEM sample holder.

12. The functionalized sleeve of claim 9, wherein the one or more extensions comprise one or more apertures aligned with a sample ring of the TEM sample holder, and wherein the apertures are aligned with an emission path of an electron beam when the TEM sample holder is inserted, while coupled to the functionalized sleeve, into a TEM column.

13. The functionalized sleeve of claim 9, wherein the cylindrical shell includes one or more alignment fixtures along an outer surface and/or an inner surface of the cylindrical shell.

14. The functionalized sleeve of claim 9, wherein the functionalized sleeve further comprises an engagement mechanism at a second end of the cylindrical shell, the second end opposite of the first end, and wherein the engagement mechanism comprises one or more alignment posts to align the functionalized sleeve with a receiving port of a TEM column.

15. The functionalized sleeve of claim 9, wherein the one or more extensions comprise an inner portion of a vacuum transfer fitting that surrounds a sample end of the TEM sample holder, and wherein the functionalized sleeve further comprises an outer portion of the vacuum transfer fitting that is configured to couple to the first end of the functionalized sleeve to isolate the sample end of the TEM sample holder from an ambient environment surrounding the functionalized sleeve.

16. A method for using a sample support apparatus comprising a functionalized sleeve, the method comprising:
loading a sample onto a sample holder of the sample support apparatus;
positioning the sample in a path of a charged particle beam;
activating stimulus components and/or detection components supported by the functionalized sleeve; and
acquiring data from the sample as the sample is irradiated by the charged particle beam.

17. The method of claim 16, further comprising coupling an outer portion of a vacuum transfer fitting to a sample end of the functionalized sleeve to maintain the sample in a low pressure environment within the vacuum transfer fitting.

18. The method of claim 17, further comprising, when the sample support apparatus is coupled to a charged particle column, adjusting the vacuum transfer fitting from a closed position to an open position to position the sample in the path of the charged particle beam.

19. The method of claim 16, wherein loading the sample comprises positioning the sample proximate to one or more extensions of the functionalized sleeve, and wherein the sample is aligned with an aperture of each of the one or more extensions when the sample is loaded.

20. The method of claim 16, wherein the sample holder is inserted into the functionalized sleeve such that a sample end of the sample holder protrudes out of a sample end of the functionalized sleeve, and wherein the sample holder is co-axial with the functionalized sleeve along lengths thereof when the sample holder is inserted into the functionalized sleeve.
